(19) United States
(12) Patent Application Publication
(10) Pub. No.: US 2026/0206224 A1
(43) Pub. Date: Jul. 16, 2026

(54) MANUFACTURING A CHARGE TRAP MEMORY SYSTEM

(71) Applicant: Micron Technology, Inc., Boise, ID (US)

(72) Inventors: Lorenzo Fratin, Buccinasco (IT); Fabio Pellizzer, Boise, ID (US); Agostino Pirovano, Milan (IT); Innocenzo Tortorelli, Cernusco Sul Naviglio (IT)

(21) Appl. No.: 19/444,040

(22) Filed: Jan. 8, 2026

Related U.S. Application Data
(60) Provisional application No. 63/745,232, filed on Jan. 14, 2025.

(51) Int. Cl. H10B 43/27; H10B 43/30

(52) U.S. Cl. CPC H10B 43/27; H10B 43/30

(57) ABSTRACT

Methods, systems, and devices for manufacturing a charge trap memory system are described. The method of manufacturing may include forming first pillars that extend through a stack of layers of the memory system, forming first cavities that extend though the stack of layers and are each positioned between respective pairs of the first pillars, forming piers in the first cavities, forming second cavities that extends through the stack of layers by removing some of the material of the first pillars, and forming second pillars in the second cavities.

### CROSS REFERENCE

The present Application for Patent claims priority to U.S. Patent Application No. 63/745,232 by Fratin et al., entitled “MANUFACTURING A CHARGE TRAP MEMORY SYSTEM,” filed January 14, 2025, which is assigned to the assignee hereof, and which is expressly incorporated by reference in its entirety herein.

### TECHNICAL FIELD

The following relates to one or more systems for memory, including manufacturing a charge trap memory system.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND or NOR) may maintain their programmed states for extended periods of time even in the absence of an external power source.

### BRIEF DESCRIPTION OF THE DRAWINGS

FIG. 1 shows an example of a memory system that supports manufacturing a charge trap memory system in accordance with examples as disclosed herein.

FIGS. 2A and 2B shows an example of a memory architecture that supports manufacturing a charge trap memory system in accordance with examples as disclosed herein.

FIGS. 3A through 3J show examples of a manufacturing process that supports manufacturing a charge trap memory system in accordance with examples as disclosed herein.

FIGS. 4A through 4H show examples of a manufacturing process that supports manufacturing a charge trap memory system in accordance with examples as disclosed herein.

FIGS. 5 and 6 show flowcharts illustrating a method or methods that support manufacturing a charge trap memory system in accordance with examples as disclosed herein.

### DETAILED DESCRIPTION

A memory system may be an example of a 3-dimensional (3D) memory system that supports charge trap memory. The memory system may include a stack of layers and multiple piers and pillars that extend through the stack of layers. The piers may house one or more memory cells configured to store one or more bits of data and the pillars may be an example of access lines (e.g., sources or drains) which may allow the memory system to access the one or more bits stored at the memory cells. In some examples, a method of manufacturing the memory system may include forming the piers prior to forming the pillars. That is, the method of manufacturing the memory system may include performing a pillar etch after depositing the piers. One problem with this method of manufacturing is that performing the pillar etch may potentially damage memory cell components of the piers (e.g., a charge trap layer of the piers).

An alternative method of manufacturing a 3D memory system that supports charge trap memory is described herein. The method of manufacturing may include forming the pillars prior to forming the piers. Specifically, the method of manufacturing may include forming first pillars that extend through a stack of layers of the memory system, forming first cavities that extend though the stack of layers and are each positioned between respective pairs of the first pillars, forming piers in the first cavities, forming second cavities that extends through the stack of layers by removing some of the material of the first pillars, and forming second pillars in the second cavities. Another example of the method of manufacturing may include forming a first cavity that extends through a stack of layers of the memory system, forming a first material in the first cavity, forming second cavities in the first material, forming piers in the second cavities, forming third cavities in the first material that are each positioned between each of the respective pairs of piers, and forming pillars in the third cavities. Using the methods of manufacturing as describe herein, the pillars may be formed prior to the piers which may decrease the potential of damage to the piers when compared to other methods of manufacturing.

In addition to applicability in memory systems as described herein, techniques for manufacturing a charge trap memory system may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by eliminating one or more failures (e.g., charge trap layer damage) in the manufacturing process, which may result in a reduction of electronic waste, among other benefits.

Features of the disclosure are illustrated and described in the context of systems, devices, and circuits. Features of the disclosure are further illustrated and described in the context of memory architectures, manufacturing processes, and flowcharts.

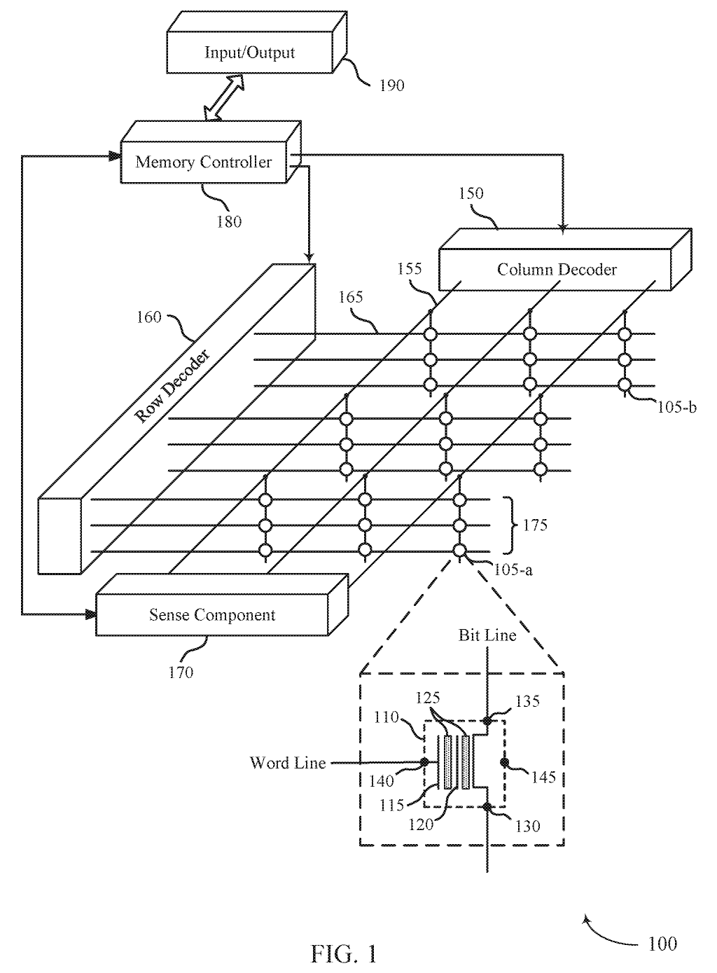

FIG. 1 shows an example of a memory system 100 that supports manufacturing a charge trap memory system in accordance with examples as disclosed herein. FIG. 1 is an illustrative representation of various components and features of the memory system 100. As such, the components and features of the memory system 100 are shown to illustrate functional interrelationships, and not necessarily physical positions within the memory system 100. Further, although some elements included in FIG. 1 are labeled with a numeric indicator, some other corresponding elements are not labeled, even though they are the same or would be understood to be similar, in an effort to increase visibility and clarity of the depicted features.

The memory system 100 may include one or more memory cells 105, such as memory cell 105-a and memory cell 105-b. In some examples, a memory cell 105 may be a charge trap NOR memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

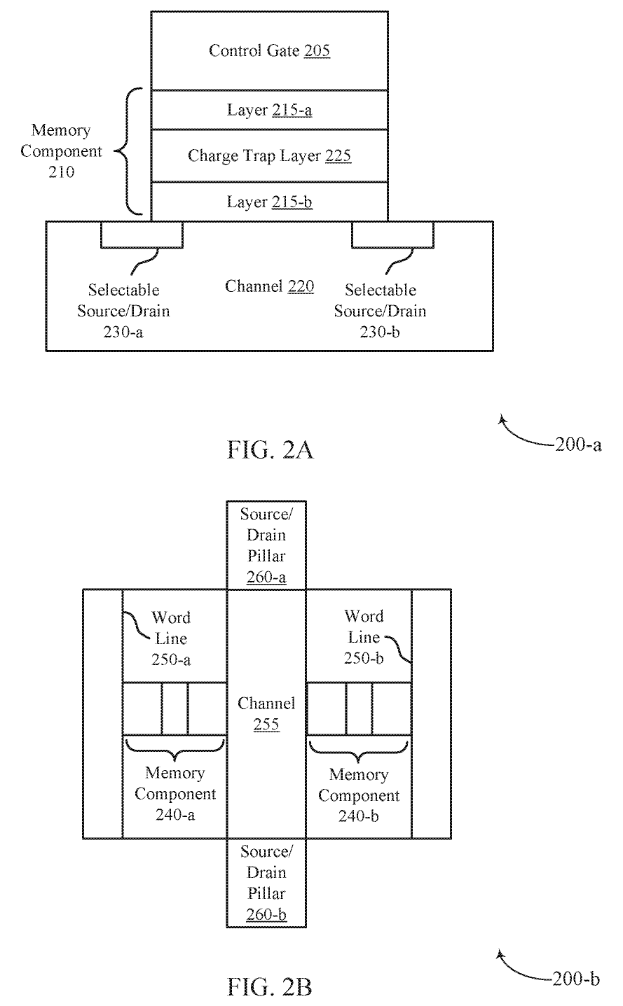

FIG. 1 illustrates a charge trap NOR memory cell 105 that includes a structure 110 that may be used to store two bits of data. The structure 110 may include a control gate 115 and a charge trap structure 120, where the charge trap structure 120 may, in some examples, be between two layers of a dielectric material 125. The control gate 115 may be coupled with a word line 140. The structure 110 may also include a first node 130 (e.g., a source or a drain), a second node 135 (e.g., a source or a drain), and a bulk node 145. One or more logic values may be stored in the memory cell 105 by storing a quantity of electron on the charge trap structure 120. One bit of data (or charge) may be stored on one end of the charge trap structure 120 and another bit of data (or charge) may be stored on the opposite end of the charge trap structure 120 resulting in two bits of data stored at the memory cell 105. Other details of the memory cell 105 are described with reference to FIG. 2A.

In some examples, piers and pillars may extend through the memory array. Each pier may house one or more memory cells 105 and may be positioned between a respective pair of pillars which allow the memory system 100 to access the one or more memory cells 105. In some examples, each pier may house two memory cells 105. In such examples, each memory cell 105 of a pier may couple with a respective word line 165 such that each memory cell 105 of the pier is separately accessible. Pillars on either side of the piers may act as source or drains. In some examples, each of the pillars may selectively couple (e.g., via a transistor) with a respective digit line or bit line 155.

To access a target memory cell 105, the column decoder 150 (e.g., gate line decoder) and a source/drain decoder may select the target memory cell 105 during programming (e.g., writing) or reading by biasing a single bit line 155 and two adjacent pillars, while the row decoder 160 may bias a word line 165 that corresponds to the target memory cell 105. The two adjacent pillars may be biased based on the access operation and the bit of data being accessed at the memory cell 105. For example, to access a first bit of the memory cell 105, a first pillar of the two adjacent pillars may be biased as a source and a second pillar of the two adjacent pillars may be biased as a drain. Alternatively, to access a second bit of the memory cell 105, the first pillar may be biased as a drain and the second pillar may be biased as a source. Techniques for accessing the memory cell 105 are further described in FIGS. 2A and 2B.

In some cases, a memory system 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory system 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

A memory controller 180 may control the operation (e.g., read, write, re-write, refresh) of memory cells 105 through the various components (e.g., row decoder 160, column decoder 150, sense component 170, input/output 190). In some cases, one or more of a row decoder 160, a column decoder 150, or a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory system 100. Data to be written to memory cells 105 may be received, and data read from memory cells 105 may be output via input/output 190.

A method of manufacturing a 3D memory system that supports charge trap memory is described herein. The method of manufacturing may include forming the pillars prior to forming the piers. Specifically, the method of manufacturing may include forming first pillars that extend through a stack of layers of the memory system, forming first cavities that extend though the stack of layers and are each positioned between respective pairs of the first pillars, forming piers in the first cavities, forming second cavities that extends through the stack of layers by removing some of the material of the first pillars, and forming second pillars in the second cavities. Another example of the method of manufacturing may include forming a first cavity that extends through a stack of layers of the memory system, forming a first material in the first cavity, forming second cavities in the first material, forming piers in the second cavities, forming third cavities in the first material that are each positioned between each of the respective pairs of piers, and forming pillars in the third cavities. Using the methods of manufacturing as describe herein, the pillars may be formed prior to the piers which may decrease the potential of damage to the piers when compared to other methods of manufacturing.

FIG. 2A shows an example of a memory architecture 200-a that supports manufacturing a charge trap memory system in accordance with examples as disclosed herein. In some examples, the memory architecture 200-a may be an example of a memory cell 105 as described with reference to FIG. 1.

As shown in FIG. 2A, the memory architecture 200-a may include a control gate 205 and a memory component 210 situated on a channel 220 that is configured to carry a current between two selectable source/drain components 230 (e.g., a selectable source/drain component 230-a and selectable source/drain components 230-b) located on either end of the channel 220. The memory architecture 200-a may be an example of a charge trap memory architecture. As such, the memory component 210 may include a charge trap layer 225 between two layers 215 (e.g., a layer 215-a and a layer 215-b). In some examples, the charge trap layer 225 may be made of nitride and the layers 215 may be made of oxide.

In some examples, the memory components 210 may be configured to store a bit of data at either end of the charge trap layer 225 (or collectively two bits). To access the bits, a current may be run through the channel 220 in different directions. For example, to write a first bit on the right side of the charge trap layer 225, the control gate 205 may be activated (e.g., biased to 9 volts), the selectable source/drain component 230-b may be selected as the drain (e.g., biased to 5 volts), and the selectable source/drain component 230-a may be selected as the source (e.g., biased to 0 volts) such that electrons may be injected from the channel 220 to the charge trap layer 225. To read the first bit, the source and drain may be reversed. That is, the selectable source/drain component 230-b may be selected as the source and the selectable source/drain component 230-a may be selected as the drain. To access a second bit of the left, similar operations are performed, but in reverse.

FIG. 2B shows an example of a memory architecture 200-b that supports manufacturing a charge trap memory system in accordance with examples as disclosed herein. In some examples, the memory architecture 200-b may be an example of a 3D memory architecture that includes multiple layers stacked upon one another. In some examples, the stack of layers may alternate between a word line layer (or a word line plane) and an oxide layer (or a word line separation plane). The memory architecture 200-b may specifically illustrate a horizontal cross section of the stack of layers taken from the word line layer of the stack of layers or a top down view of the word line layer.

As shown in FIG. 2B, at the word line layer, the memory architecture 200-b may be divided into a left side and a right side by a channel 255. Each side may include a separately accessible memory component 240. For example, at the word line layer, the left side of the memory architecture 200-b may include a memory component 240-a situated between a word line 250-a and the channel 255. Similarly, at the word line layer, the right side of the memory architecture 200-b may include a memory component 240-b situated between a word line 250-b and the channel 255. Further, each end of the channel 255 may couple with a respective source/drain pillar 260 (e.g., a source/drain pillar 260-a and a source/drain pillar 260-b). In some examples, the source/drain pillars 260 may run in a direction than is perpendicular to the word line layer or the word lines 250. That is, the source/drain pillars 260 may run vertically through the stack of layers.

In some examples, the memory architecture 200-b may incorporate aspects of the memory architecture 200-a. For example, the word lines 250 may examples of a control gate 205, the memory components 240 may be examples of the memory component 210, the channel 255 may be an example of the channel 220, and the source/drain pillars 260 may be examples of the selectable source/drain components 230 as described in FIG. 2A. Further, the memory architecture 200-b may operate in a similar manner as the memory architecture 200-a. That is, each memory component 240 (e.g., the memory component 240-a and the memory component 240-b) may be configured to store 2 bits which may be accessed by selectively switching the designation of the selectable source/drain pillars 260 and activating a respective word line 250.

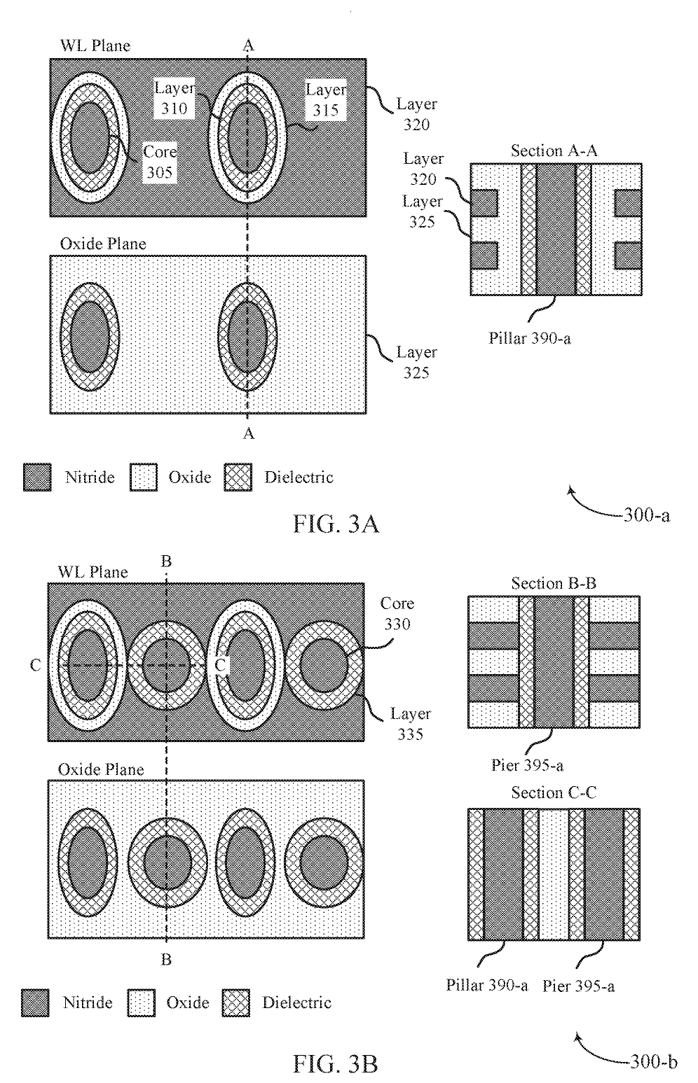

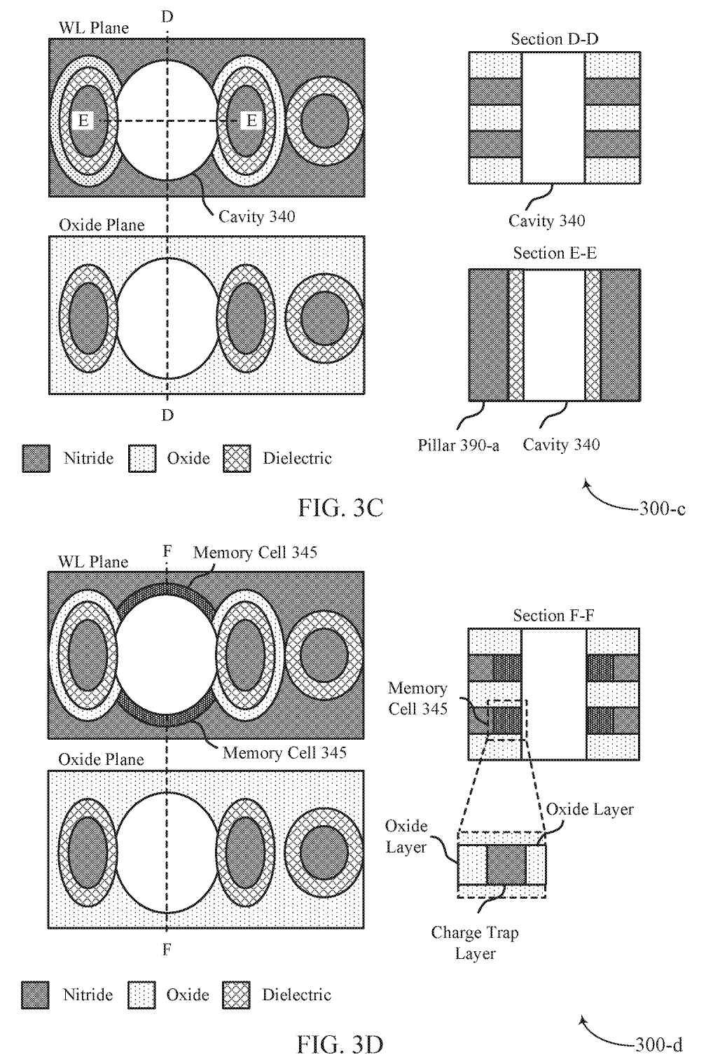

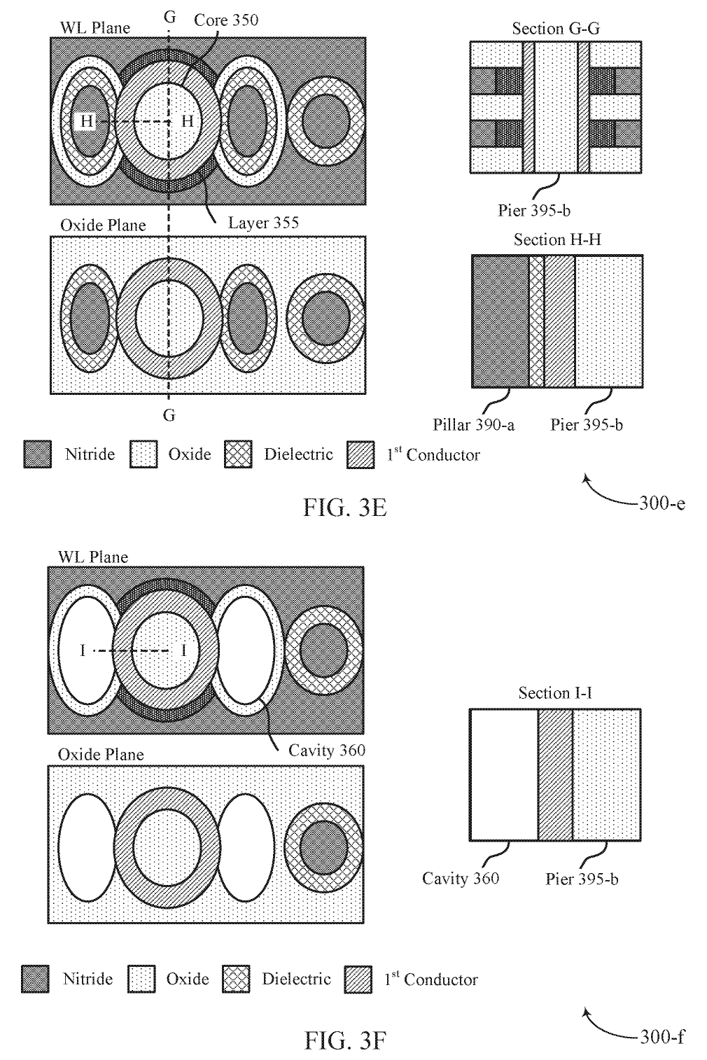

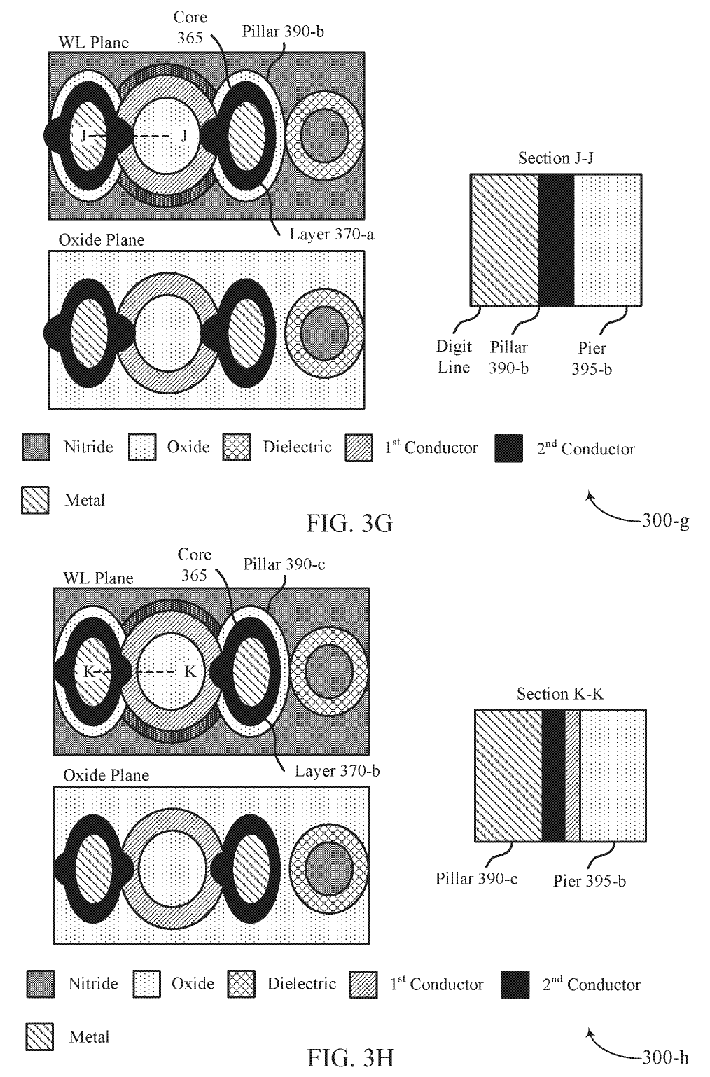

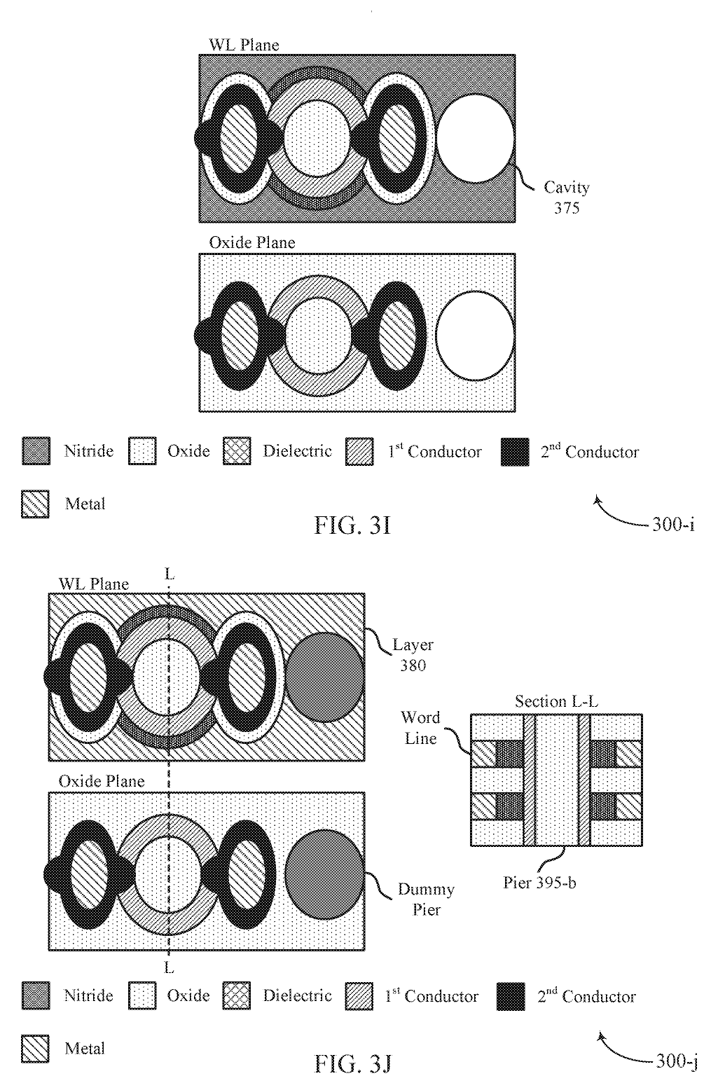

FIGS. 3A through 3J show examples of a portion 300 (e.g., a portion 300-a, a portion 300-b, a portion 300-c, a portion 300-d, a portion 300-e, a portion 300-f, a portion 300-g, a portion 300-h, a portion 300-i, and a portion 300-j) after a manufacturing process that supports manufacturing a charge trapping memory system in accordance with examples as disclosed herein. In some examples, each of the FIGS. 3A through 3J may illustrate a top view of a respective portion 300 from a word line plane, a top view of the respective portion 300 from an oxide plane, and one or more cross section views of the respective portion 300. In some examples, the portions 300 may be examples of the memory architecture 200-b during different stages of the manufacturing process.

To create the portion 300-a of FIG. 3A, the manufacturing process may include one or more first operations. In some examples, the one or more first operations may include forming a stack of layers that includes one or more layers 320 and one or more layers 325. The one or more layers 320 may include a nitride material and the one or more layers 325 may include an oxide material. In some examples, the stack of layers may alternate between a layer 320 of the one or more layers 320 and a layer 325 of the one or more layers 325. Additionally, the one or more first operations may include forming one or more first cavities through the stack of layers by removing (or etching) some of the material of the stack of layers. Additionally, the one or more first operations may include removing some of the nitride material (or performing nitride recession) at the one or more layers 320 through the one or more first cavities to widen the one or more first cavities at the one or more layers 320.

Additionally, the one or more first operations may include forming (or depositing) the oxide material in the one or more first cavities. Additionally, the one or more first operations may include forming one or more second cavities in the oxide material by removing (or etching) some of the oxide material and forming a dielectric material (e.g., aluminum oxide (AlOx), hafnium oxide (HfOx), silicon carbonitride (SiCN), or Silicon oxycarbide (SiOC)) in the one or more second cavities. Further, the one or more first operations may include forming one or more third cavities in the dielectric material by removing some of the dielectric material and forming the nitride material in the one or more third cavities.

In some examples, the deposition of the oxide material may include selective deposition. In such example, the one or more second cavities may be formed without removing the oxide material. Further, in some examples, the deposition of the oxide material, the dielectric material, and the nitride material may include a sequence of conformal depositions. In such example, the one or more second cavities and the one or more third cavities may be formed without removing the oxide material and the dielectric material. Further, in some examples, isotropic etching may be performed on the dielectric material, the oxide material, or the nitride material to trim a lateral thickness and/or anisotropic etching may be performed on the dielectric material, the oxide material, or the nitride material to remove any excess material that may be present at the bottom of the cavities (e.g., the one or more first cavities, the one or more second cavities, or the one or more third cavities).

As a result of the one or more first operations, one or more pillars 390-a may be formed through the stack of layers. The one or more pillars 390-a may include a core 305 made of the nitride material, a layer 310 made of the dielectric material, and a layer 315 made of the oxide material. In some examples, an outer surface of the core 305 may couple (or be in contact) with the layer 310, an outer surface of the layer 310 may couple (or be in contact) with the layer 325, and an outer surface of the layer 315 may couple (or be in contact) with the layer 320 and the layer 325. Section A-A illustrates a cross-section of the stack of layers of the portion 300-a taken from a pillar 390-a of the one or more pillars 390-a.

To create the portion 300-b of FIG. 3B, the manufacturing process may include one or more second operations. In some examples, the one or more second operations may include forming one or more fourth cavities through the stack of layers by removing (or etching) some of the stack of layers. In some examples, each fourth cavity of the one or more fourth cavities may be positioned between a respective pair of pillars 390-a. Additionally, the one or more second operations may include forming the dielectric material in the one or more fourth cavities. Additionally, the one or more second operations may include forming one or more fifth cavities by removing some of the dielectric material and forming the nitride material in the one or more fifth cavities. In some examples, the deposition of the dielectric material may include selective deposition. In such example, the one or more fifth cavities may be formed without removing the dielectric material.

As a result of the one or more second operations, one or more piers 395-a may be formed through the stack of layers. The one or more piers 395-a may include a core 330 made of the nitride material and a layer 335 made of the dielectric material. In some examples, an outer surface of the core 330 may couple (or be in contact) with the layer 335 and an outer surface of the layer 335 may couple (or be in contact) with the layer 320 and the layer 325. Section B-B illustrates a cross-section of the of the stack of layers of the portion 300-b taken from a pier 395-a of the one or more piers 395-a. Section C-C illustrates a cross-section of the stack of layers of the portion 300-b taken from the pier 395-a and a neighboring pillar 390-a.

To create the portion 300-c of FIG. 3C, the manufacturing process may include one or more third operations. In some examples, the one or more third operations may include forming a cavity 340 by removing (or performing a masked exhume of) the nitride material and the dielectric material of the pier 395-a and additionally, removing some of the oxide material of the neighboring pillars 390-a (or the pillars 390-a located on either side of the pier 395-a) such that the layer 310 of neighboring pillars 390-a is exposed through the cavity 340. In some examples, a hydrofluoric acid (HF) selective to the dielectric material may be used to form the cavity 340. As shown in FIG. 3D, at least one pier 395-a (e.g., a dummy pier) of the one or more piers 395-a may remain intact. Section E-E illustrates a cross-section of the stack of layers of the portion 300-c taken from the cavity 340 and neighboring pillars 390-a. Section D-D illustrates a cross-section of the stack of layers of the portion 300-c taken from the cavity 340.

To create the portion 300-d of FIG. 3D, the manufacturing process may include one or more fourth operations. In some examples, the one or more fourth operations may include removing some of the nitride material from the one or more layers 320 through the cavity 340 to form voids between each respective pair of layers 325. In some examples, the recession of the nitride material may be selective towards the oxide material. Additionally, the one or more fourth operations may include forming memory cells 345 at each layer 320 of the one or more layers 320. In some examples, a memory cell 345 may be examples of the memory component 210 or the memory component 240 as described with reference to FIGS. 2A and 2B, respectively. Forming the memory cells 345 may include depositing memory cell material in the cavity 340 and removing some of the memory cell material to form memory cells 345 that are contained in the voids. Further, removing some of the memory cell material may form a sixth cavity through the stack of layers.

In some examples, each memory cell 345 may include multiple layers of materials. For example, each memory cell 345 may include a charge trap layer (or a nitride layer) positioned between two dielectric (or oxide) layers. In some examples, one of the dielectric layers of a memory cell 245 may be adjacent to (or in contact with) the nitride material of a respective layer 320 and the other dielectric layer of the memory cell 245 may be adjacent to the sixth cavity. In some examples, one or both of the charge trap layer or the dielectric layer (e.g., the dielectric layer closest to the cavity 340) may not be contained in the voids. Instead, one or both of the charge trap layer or the dielectric layer may coat one or more surfaces of material exposed by the cavity 340. Section F-F illustrates a cross-section of the stack of layers of the portion 300-d taken from the memory cells 345.

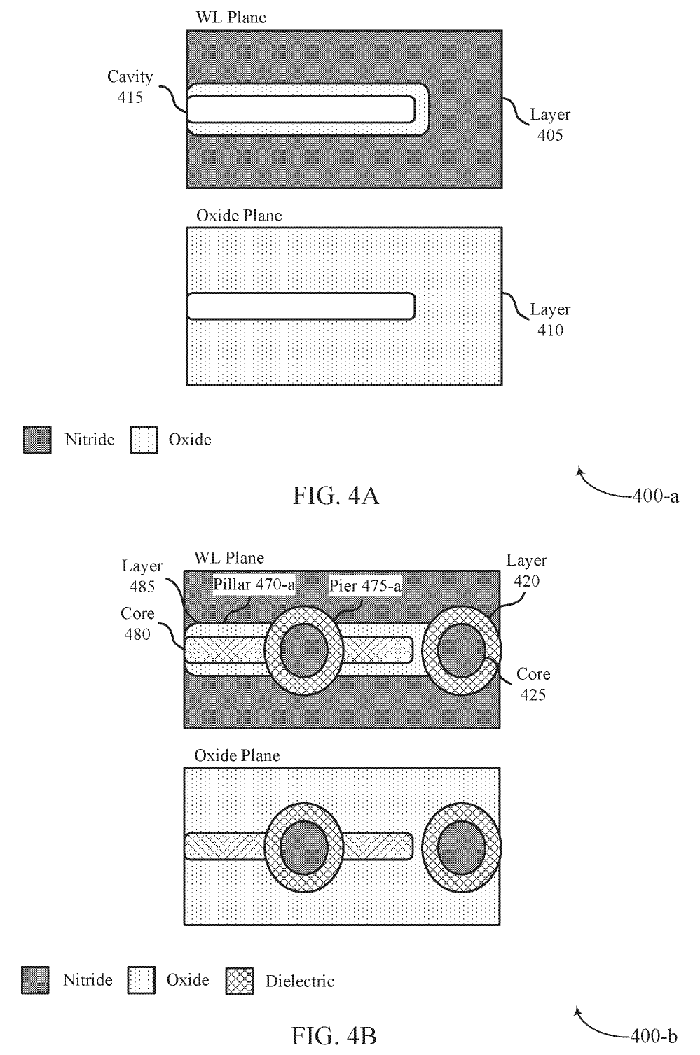

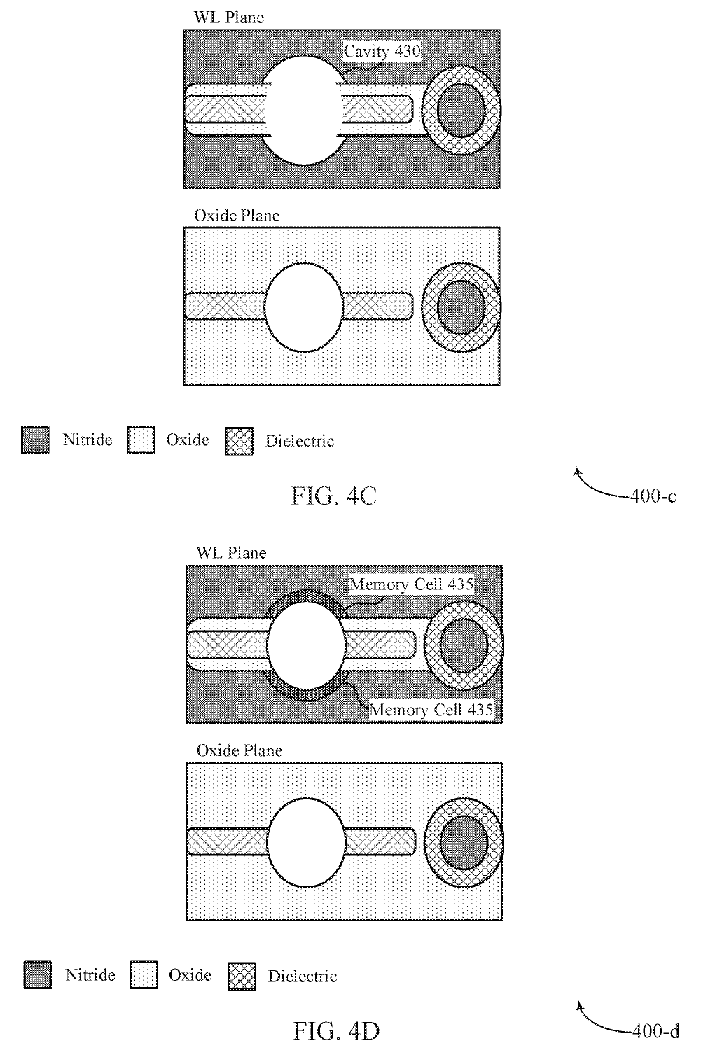

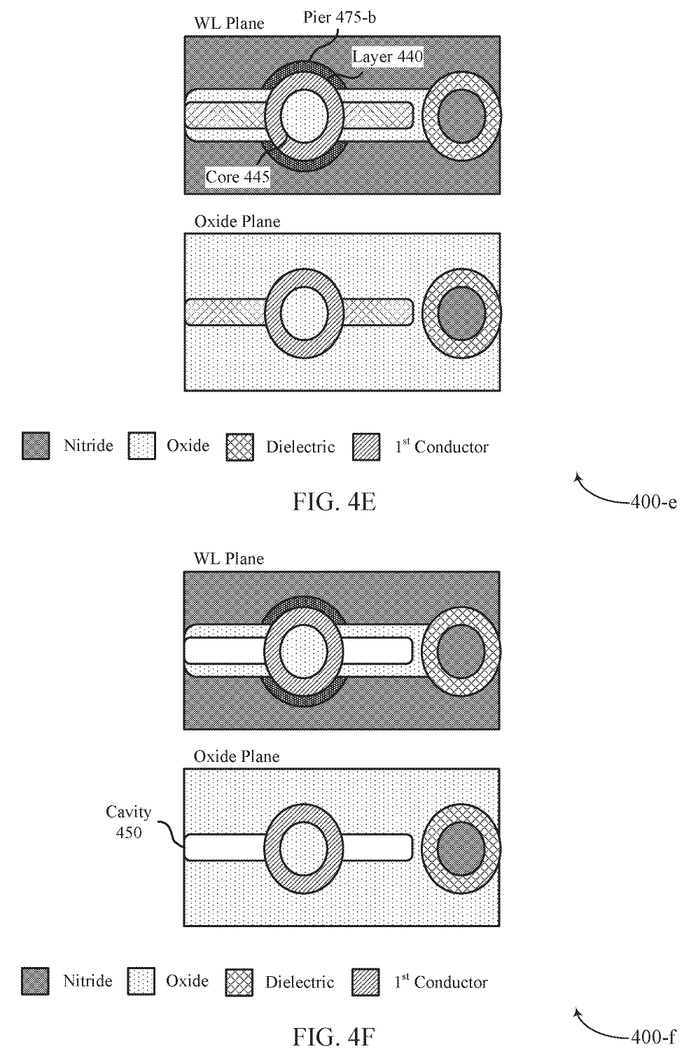

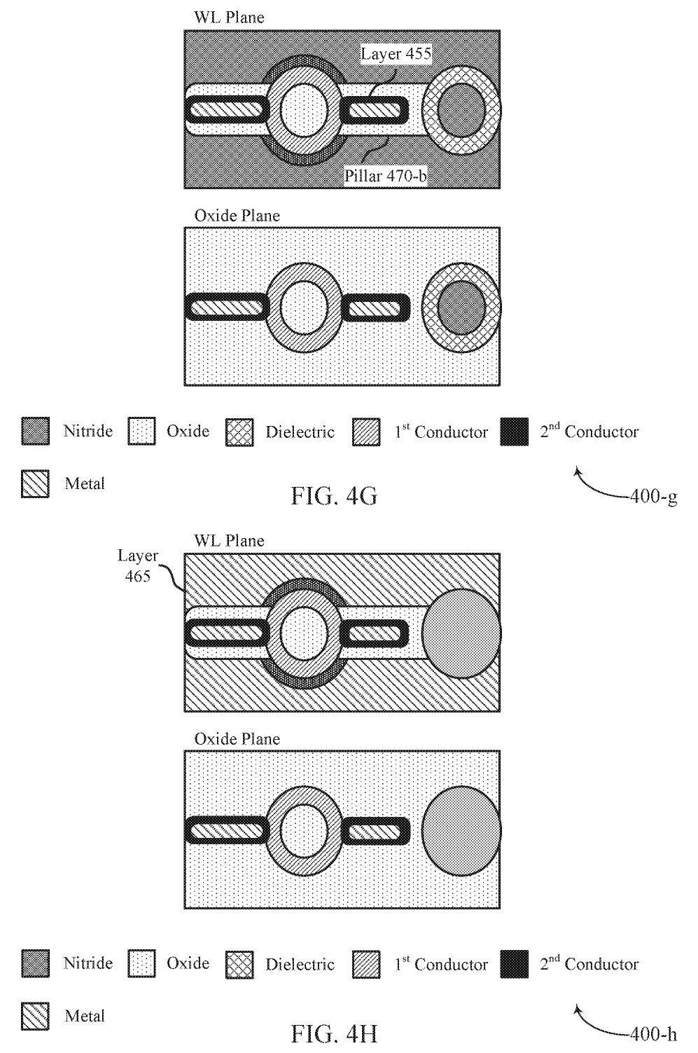

To create the portion 300-e of FIG. 4E, the manufacturing process may include one or more fifth operations. In some examples, the one or more fifth operations may include forming (or depositing) a first conductive material (or p-type poly-silicon) in the sixth cavity and removing a portion of the first conductive material to create a seventh cavity. Additionally, the one or more fifth operations may include forming (or depositing) the oxide material in the seventh cavity. In some examples, the deposition of the first conductive material may include selective deposition. In such example, the seventh cavity may be formed without removing the first conductive material.

As a result of the one or more fifth operations, one or more piers 395-b may be formed through the stack of layers. The one or more piers 395-b may include a core 350 made of the oxide material, a layer 355 made of the first conductive material, and memory cells 245. In some examples, an outer surface of the core 350 may couple (or be in contact) with the layer 355 and an outer surface of the layer 355 may couple (or be in contact) with the memory cells 245. Section G-G illustrates a cross-section of the of the stack of layers of the portion 300-e taken from a pier 395-b of the one or more piers 395-b. Section H-H illustrates a cross-section of the stack of layers of the portion 300-e taken from the pier 395-b and a neighboring pillar 390-a.

To create the portion 300-f of FIG. 3F, the manufacturing process may include one or more sixth operations. In some examples, the one or more sixth operations may include forming one or more cavities 360 through the stack of layers by removing (or exhuming) the nitride material and removing the dielectric material from the one or more pillars 390-a. In some examples, removing the dielectric material may include using a wet etch back selective to the oxide material, the nitride material, and the first conductive material. Section I-I illustrate a cross section of the stack of layers of the portion 300-f taken from a cavity 360 of the one or more cavities and a neighboring pier 395-b.

To create the portion 300-g of FIG. 3G, the manufacturing process may include one or more seventh operations. In some examples, the one or more seventh operations may include removing (e.g., via a lateral wet etch) some of the first conductive material of the layer 355 of the pier 395-b through the one or more cavities 360 such that the core 350 of the one or more piers 395-b is exposed through the one or more cavities 360. Additionally, the one or more seventh operations may include forming (or depositing) a second conductive material (e.g., an n-type polysilicon) in the one or more cavities 360 and removing some of the second conductive material to form one or more eighth cavities through the stack of layers. Additionally, the one or more seventh operations may include forming a metal material in the one or more eighth cavities. In some examples, the deposition of the second conductive material may include selective deposition. In such example, the one or more eighth cavities may be formed without removing the second conductive material.

As a result of the one or more seventh operations, one or more pillars 390-b may be formed through the stack of layers. The one or more pillars 390-b may include a core 365 made of the metal material and a layer 370-a made of the second conductive material. In some examples, an outer surface of the core 365 may couple (or be in contact) with the layer 370-a and the layer 370-a may couple (or be in contact) with a core 350 of the one or more cores 350. In some examples, the core 365 may be an example of a digit line, a source line, or a drain line. Section J-J illustrates a cross-section of the stack of layers of the portion 300-g taken from the pier 395-b and a neighboring pillar 390-b.

Alternative to the one or more seventh operations, the manufacturing process may include one or more eighth operations to create the portion 300-h of FIG. 3H. In some examples, the one or more eighth operations may include removing (e.g., via a partial lateral wet etch) some of the first conductive material of the layer 355 of the pier 395-b through the cavity 360 such that the first conductive material of the layer 355 is exposed through the one or more cavities 360. Additionally, the one or more eighth operations may include forming (or depositing) the second conductive material in the one or more cavities 360 and removing some of the second conductive material to form one or more ninth cavities. Additionally, the one or more eighth operations may include forming a metal material in the one or more ninth cavities.

As a result of the one or more eighth operations, one or more pillars 390-c may be formed through the stack of layers. The one or more pillars 390-c may include the core 365 made of the metal material and a layer 370-b made of the second conductive material. In some examples, the core 365 may couple (or be in contact) with the layer 370-b and the layer 370-b may couple (or be in contact) with the layer 355. Section K-K illustrates a cross-section of the stack of layers of the portion 300-h taken from the pier 395-b and a neighboring pillar 390-c. In some examples, the pillar 390-b and the pillar 390-c may be an example of the source/drain pillars 260 as described with reference to FIG. 2B.

To create the portion 300-i of FIG. 3I, the manufacturing process may include one or more ninth operations. In some examples, the one or more ninth operations may include removing (or mask exhuming) the nitride material and the dielectric material from the remaining pier 395-a to form a cavity 375 through the stack of layers.

To create the portion 300-j of FIG. 3J, the manufacturing process may include one or more tenth operations. In some examples, the one or more tenth operations may include forming dummy material in the cavity 375. Additionally, the one or more tenth operations may include removing the nitride material from the layers 320 to form voids between the layers 325. Additionally, the one or more tenth operations may include forming layers 380 by forming (or depositing) the metal material in the voids. As a result of the one or more tenth operations, one or more word lines may be formed in the stack of layers. For example, a layer 380 may be divided into two word lines (e.g., a top word line and a bottom word line) and each word line may couple with one or more respective memory cells 345 of the layer 380. Section L-L illustrates a cross-section of the stack of layers of the portion 300-j taken from the pier 395-b. In some examples, the portion 300-j may be an example of the memory architecture 200-b as illustrated in FIG. 2B.

The portion 300-j may only be illustrative of a portion of a 3D memory array. It should be understood that the WL plane may be extended to include more piers 395 and more pillars 390 than what is illustrated in FIG. 3J. That is, the vertical structure of memory cells as illustrated in FIG. 3J may be combined with other vertical structures of memory cells inside the 3D memory array to form a comb structure.

FIGS. 4A through 4H show examples of a portion 400 (e.g., a portion 400-a, a portion 400-b, a portion 400-c, a portion 400-d, a portion 400-e, a portion 400-f, a portion 400-g, and a portion 400-h) after a manufacturing process that supports manufacturing a charge trapping memory system in accordance with examples as disclosed herein. In some examples, each of the FIGS. 4A through 4H may illustrate a top view of a respective portion 400 from a word line plane, a top view of the respective portion 400 from an oxide plane, and one or more cross-sectional views of the respective portion 400. In some examples, the portion 400 may be an example of the memory architecture 200-b during different stages of the manufacturing process.

To create the portion 400-a of FIG. 4A, the manufacturing process may include one or more first operations. In some examples, the one or more first operations may include forming a stack of layers that include one or more layers 405 and one or more layers 410. The one or more layers 405 may include nitride material and the one or more layers 410 may include oxide material. In some examples, the stack of layers may alternate between a layer 405 of the one or more layers 405 and a layer 410 of the one or more layers 410. Additionally, the one or more first operations may include forming a first cavity through the stack of layers by removing some of the material of the stack of layers. Additionally, the one or more first operations may include removing some of the nitride material at the one or more layers 405 through the first cavity to widen the first cavity at the one or more layers 405. Additionally, the one or more first operations may include forming oxide material in the first cavity and forming a cavity 415 though the stack of layers by removing some of the oxide material.

To create the portion 400-b of FIG. 4B, the manufacturing process may include one or more second operations. In some examples, the one or more second operations may include forming a dielectric material (e.g., AlOx, HfOx, SiCN, or SiOC) in the cavity 415. Further, the one or more second operations may include forming one or more second cavities through the stack of layers by removing some of the stack of layers, some of the dielectric material, and some of the oxide material. Additionally, the one or more second operations may include forming the dielectric material in the one or more second cavities. Additionally, the one or more second operations may include forming one or more third cavities by removing some of the dielectric material and forming the nitride material in the one or more third cavities. In some examples, the deposition of the dielectric material may include selective deposition. In such example, the one or more third cavities may be formed without removing the dielectric material.

As a result of the one or more second operations, one or more pillars 470-a and one or more piers 475-a may be formed through the stack of layers. Each pier 475-a may be positioned between a respective pair of pillars 470. Further, the one or more pillars 470-a may include a core 480 made of the dielectric material and a layer 385 made of the oxide material. In some examples, an outer surface of the core 480 may couple (or be in contact) with the layer 485 and an outer surface of the layer 485 may couple (or be in contact) with the layer 405 and the layer 410. The one or more piers 475-a may include a core 425 made of the nitride material and a layer 420 may of the dielectric material. In some examples, an outer surface of the core 425 may couple (or be in contact) with the layer 420 and an outer surface of the layer 420 may couple (or be in contact) with the layer 405 and the layer 410.

To create the portion 400-c of FIG. 4C, the manufacturing process may include one or more third operations. In some examples, the one or more third operations may include forming a fourth cavity by removing the nitride material and the dielectric material that make up a pier 475-a. Additionally, the one or more third operations may include removing some of the nitride material from the one or more layers 405 through the fourth cavity creating a cavity 430 through the stack of layers and voids between each respective pair of layers 410. In some examples, the recession of the nitride material may be selective towards the oxide material. As shown in FIG. 4C, at least one pier 475-a of the one or more piers 475-a (e.g., a dummy pier) may remain intact.

To create the portion 400-d of the FIG. 4D, the manufacturing process may include one or more fourth operations. In some examples, the one or more fourth operations may include forming memory cells 435 at each layer 405. Forming the memory cells 435 may include depositing memory cell materials in the cavity 430 and removing some of the memory cell materials to form memory cells 435 that are contained within the voids. Further, removing some of the memory cell materials may form a fifth cavity through the stack of layers. In some examples, each memory cell 435 may include multiple layers of materials. For example, each memory cell 435 may include a charge trapping layer (or a nitride layer) positioned between two oxide layers. In some examples, one of the oxide layers of a memory cell 435 may be adjacent to (or in contact with) the nitride material of a respective layer 405 and the other oxide layer of the memory cell 435 may be adjacent to the fifth cavity. In some examples, the memory cell 435 may be an example of the memory component 210 or the memory component 240 as described with reference to FIG. 2A and FIG. 2B, respectively.

To create the portion 400-e of FIG. 4E, the manufacturing process may include one or more fifth operations. In some examples, the one or more fifth operations may include forming a first conductive material (or p-type polysilicon) in the fifth cavity and removing a portion of the first conductive material to create a sixth cavity. Additionally, the one or more fifth operations may include forming the oxide material in the sixth cavity. In some examples, the deposition of the first conductive material may include selective deposition. In such example, the sixth cavity may be formed without removing the first conductive material. As a result of the one or more fifth operations, one or more piers 475-b may be formed through the stack of layers. The one or more piers 475-b may include a core 445 made of the oxide material, a layer 440 made of the first conductive material, and memory cells 435. In some examples, an outer surface of the core 445 may couple (or be in contact) with the layer 440 and an outer surface of the layer 440 may couple (or be in contact) with the memory cells 435.

To create the portion 400-f of FIG. 4F, the manufacturing process may include one or more sixth operations. In some examples, the one or more sixth operations may include forming one or more cavities 450 through the stack of layers by removing the dielectric material from the one or more pillars 470-a.

To create the portion 400-g of FIG. 4G, the manufacturing process may include one or more seventh operations. In some examples, the one or more seventh operations may include removing some of the first conductive material of the one or more piers 475-b through the one or more cavities 450 such that a portion of the first conductive material of the one or more piers 475-b is exposed through the one or more cavities 450. Additionally, the one or more seventh operations may include forming a second conductive material (or n-type polysilicon) in the one or more cavities 450 and removing some of the second conductive material to form one or more seventh cavities through the stack of layers. Additionally, the one or more seventh operations may include forming a metal material in the one or more seventh cavities. In some examples, the deposition of the second conductive material may include selective deposition. In such example, the one or more seventh cavities may be formed without removing the second conductive material.

As a result of the one or more seventh operations, one or more pillars 470-b may be formed through the stack of layers. The one or more pillars 470-b may include a core made of the metal material and a layer 455 made of the second conductive material. In some examples, an outer surface of the core may couple (or be in contact) with the layer 455 and the layer 455 may couple (or be in contact) with the layer 440 of the one or more piers 475-b. In some examples, the pillar 470-b may be an example of the source/drain pillars 260 as described with reference to FIG. 2B.

To create the portion 300-h of FIG. 3H, the manufacturing process may include one or more eighth operations. In some examples, the one or more eighth operations may include removing the nitride material and the dielectric material from the remaining pier 475-a to form an eighth through the stack of layers. Further, the one or more eighth operations may include forming dummy material in the eighth cavity. Additionally, the one or more eighth operations may include removing the nitride material from the layers 405 to form voids between the layers 410. Additionally, the one or more eighth operations may include forming layers 465 by forming the metal material in the voids. As a result of the one or more eighth operations, one or more word lines may be formed in the stack of layers. Each memory cell 435 may be coupled with a respective word line and a respective digit line via a channel (or layer 440). In some examples, the portion 400-h may be an example of the memory architecture 200-a as illustrated in FIG. 2B.

The portion 400-h may only be illustrative of a portion of a 3D memory array. It should be understood that WL plane may be extended to include more piers 475-b and more pillars 470-b than what is illustrated in FIG. 4H. In the case that the 3D memory array includes multiple rows of the piers 475-b and more pillars 470-b (e.g., the portion 400-h is repeated in the vertical direction), the rows may be staggered such that a pier 475-a of a first row is located between two adjacent piers 475-a of a second row resulting in a more compact design. That is, the vertical structure of memory cells as illustrated in FIG. 4H may be combined with other vertical structures of memory cells inside the 3D memory array to form a comb structure.

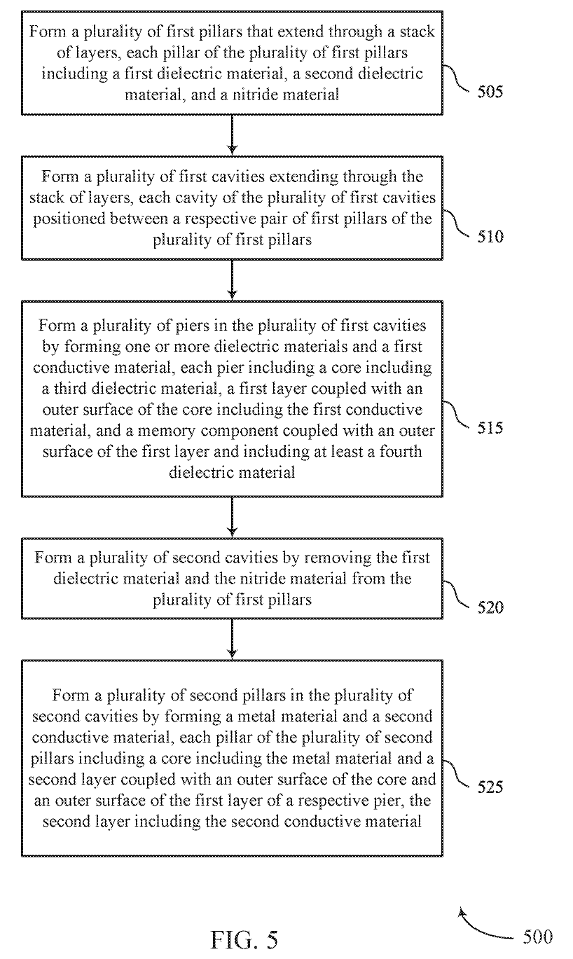

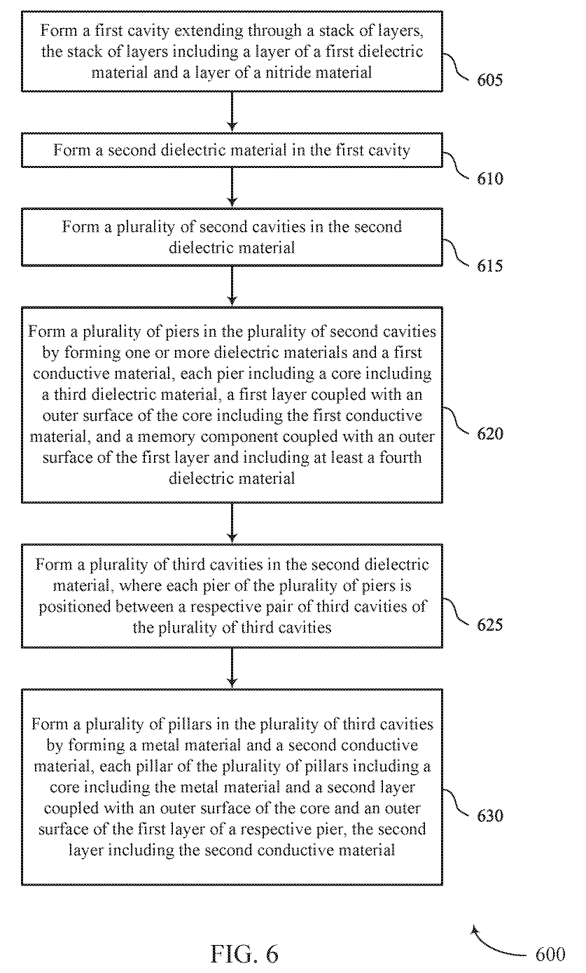

FIG. 5 shows a flowchart illustrating a method 500 that supports manufacturing a charge trap memory system in accordance with examples as disclosed herein. The operations of method 500 may be implemented by a manufacturing system or its components as described herein. In some examples, a manufacturing system may execute a set of instructions to control the functional elements of the device to perform the described functions. Additionally, or alternatively, the manufacturing system may perform aspects of the described functions using special-purpose hardware.

At 505, the method may include forming a plurality of first pillars that extend through a stack of layers, each pillar of the plurality of first pillars including a first dielectric material, a second dielectric material, and a nitride material.

At 510, the method may include forming a plurality of first cavities extending through the stack of layers, each cavity of the plurality of first cavities positioned between a respective pair of first pillars of the plurality of first pillars.

At 515, the method may include forming a plurality of piers in the plurality of first cavities by forming one or more dielectric materials and a first conductive material, each pier including a core including a third dielectric material, a first layer coupled with an outer surface of the core including the first conductive material, and a memory component coupled with an outer surface of the first layer and including at least a fourth dielectric material.

At 520, the method may include forming a plurality of second cavities by removing the first dielectric material and the nitride material from the plurality of first pillars.

At 525, the method may include forming a plurality of second pillars in the plurality of second cavities by forming a metal material and a second conductive material, each pillar of the plurality of second pillars including a core including the metal material and a second layer coupled with an outer surface of the core and an outer surface of the first layer of a respective pier, the second layer including the second conductive material.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a plurality of first pillars that extend through a stack of layers, each pillar of the plurality of first pillars including a first dielectric material, a second dielectric material, and a nitride material; forming a plurality of first cavities extending through the stack of layers, each cavity of the plurality of first cavities positioned between a respective pair of first pillars of the plurality of first pillars; forming a plurality of piers in the plurality of first cavities by forming one or more dielectric materials and a first conductive material, each pier including a core including a third dielectric material, a first layer coupled with an outer surface of the core including the first conductive material, and a memory component coupled with an outer surface of the first layer and including at least a fourth dielectric material; forming a plurality of second cavities by removing the first dielectric material and the nitride material from the plurality of first pillars; and forming a plurality of second pillars in the plurality of second cavities by forming a metal material and a second conductive material, each pillar of the plurality of second pillars including a core including the metal material and a second layer coupled with an outer surface of the core and an outer surface of the first layer of a respective pier, the second layer including the second conductive material.

Aspect 2: The method, apparatus, or non-transitory computer-readable medium of aspect 1, where the stack of layers include at least a layer of the nitride material and a layer of a fifth dielectric material.

Aspect 3: The method, apparatus, or non-transitory computer-readable medium of aspect 2, further including operations, features, circuitry, logic, means, or instructions, or any combination thereof for forming the memory component by removing a portion of the layer of the nitride material through a first cavity of the plurality of first cavities.

Aspect 4: The method, apparatus, or non-transitory computer-readable medium of any of aspects 2 through 3, further including operations, features, circuitry, logic, means, or instructions, or any combination thereof for forming a void in the stack of layers by removing the layer of the nitride material and forming a layer of the metal material in the stack of layers by forming the metal material in the void.

Aspect 5: The method, apparatus, or non-transitory computer-readable medium of any of aspects 1 through 4, further including operations, features, circuitry, logic, means, or instructions, or any combination thereof for forming a plurality of third cavities through the stack of layers; forming a plurality of second piers in the plurality of third cavities by forming the nitride material and a fifth dielectric, where forming the plurality of first cavities includes; and removing the nitride material and fifth dielectric material from the plurality of second piers.

Aspect 6: The method, apparatus, or non-transitory computer-readable medium of aspect 5, where a diameter of a first cavity of the plurality of first cavities is larger than a diameter of a third cavity of the plurality of third cavities.

Aspect 7: The method, apparatus, or non-transitory computer-readable medium of any of aspects 5 through 6, further including operations, features, circuitry, logic, means, or instructions, or any combination thereof for exposing at least some of an outer surface of the first dielectric material of a first pillar of the plurality of first pillars based at least in part on forming a first cavity of the plurality of first cavities.

Aspect 8: The method, apparatus, or non-transitory computer-readable medium of any of aspects 1 through 7, further including operations, features, circuitry, logic, means, or instructions, or any combination thereof for forming a plurality of first conductive paths at a first side of a pier of the plurality of piers and a plurality of second conductive paths at a second side of the pier, the plurality of first conductive paths and the plurality of second conductive paths dividing the memory component of the pier into a plurality of first memory cells and a plurality of second memory cells.

Aspect 9: The method, apparatus, or non-transitory computer-readable medium of aspect 8, where each of the plurality of first memory cells and each of the plurality of second memory cells are configured to store two or more bits of data.

Aspect 10: The method, apparatus, or non-transitory computer-readable medium of any of aspects 1 through 9, where the memory component includes a second stack of layers, the second stack of layers including a first layer of an oxide material, a second layer of the nitride material, and a third layer of the oxide material.

FIG. 6 shows a flowchart illustrating a method 600 that supports manufacturing a charge trap memory system in accordance with examples as disclosed herein. The operations of method 600 may be implemented by a manufacturing system or its components as described herein. In some examples, a manufacturing system may execute a set of instructions to control the functional elements of the device to perform the described functions. Additionally, or alternatively, the manufacturing system may perform aspects of the described functions using special-purpose hardware.

At 605, the method may include forming a first cavity extending through a stack of layers, the stack of layers including a layer of a first dielectric material and a layer of a nitride material.

At 610, the method may include forming a second dielectric material in the first cavity.

At 615, the method may include forming a plurality of second cavities in the second dielectric material.

At 620, the method may include forming a plurality of piers in the plurality of second cavities by forming one or more dielectric materials and a first conductive material, each pier including a core including a third dielectric material, a first layer coupled with an outer surface of the core including the first conductive material, and a memory component coupled with an outer surface of the first layer and including at least a fourth dielectric material.

At 625, the method may include forming a plurality of third cavities in the second dielectric material, where each pier of the plurality of piers is positioned between a respective pair of third cavities of the plurality of third cavities.

At 630, the method may include forming a plurality of pillars in the plurality of third cavities by forming a metal material and a second conductive material, each pillar of the plurality of pillars including a core including the metal material and a second layer coupled with an outer surface of the core and an outer surface of the first layer of a respective pier, the second layer including the second conductive material.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 11: A method, apparatus, or non-transitory computer-readable medium including operations, features, circuitry, logic, means, or instructions, or any combination thereof for forming a first cavity extending through a stack of layers, the stack of layers including a layer of a first dielectric material and a layer of a nitride material; forming a second dielectric material in the first cavity; forming a plurality of second cavities in the second dielectric material; forming a plurality of piers in the plurality of second cavities by forming one or more dielectric materials and a first conductive material, each pier including a core including a third dielectric material, a first layer coupled with an outer surface of the core including the first conductive material, and a memory component coupled with an outer surface of the first layer and including at least a fourth dielectric material; forming a plurality of third cavities in the second dielectric material, where each pier of the plurality of piers is positioned between a respective pair of third cavities of the plurality of third cavities; and forming a plurality of pillars in the plurality of third cavities by forming a metal material and a second conductive material, each pillar of the plurality of pillars including a core including the metal material and a second layer coupled with an outer surface of the core and an outer surface of the first layer of a respective pier, the second layer including the second conductive material.

Aspect 12: The method, apparatus, or non-transitory computer-readable medium of aspect 11, further including operations, features, circuitry, logic, means, or instructions, or any combination thereof for forming the memory component by removing a portion of the layer of the nitride material through a second cavity of the plurality of second cavities.

Aspect 13: The method, apparatus, or non-transitory computer-readable medium of any of aspects 11 through 12, further including operations, features, circuitry, logic, means, or instructions, or any combination thereof for forming a void in the stack of layers by removing the layer of the nitride material and forming a layer of the metal material in the stack of layers by forming the metal material in the void.

Aspect 14: The method, apparatus, or non-transitory computer-readable medium of any of aspects 11 through 13, further including operations, features, circuitry, logic, means, or instructions, or any combination thereof for forming a plurality of fourth cavities through the stack of layers; forming a plurality of second piers in the plurality of fourth cavities by forming the nitride material and a third dielectric, where forming the plurality of second cavities includes; and removing the nitride material and the third dielectric material from the plurality of second piers.

Aspect 15: The method, apparatus, or non-transitory computer-readable medium of aspect 14, where a diameter of a second cavity of the plurality of second cavities is larger than a diameter of a fourth cavity of the plurality of fourth cavities.

Aspect 16: The method, apparatus, or non-transitory computer-readable medium of any of aspects 14 through 15, further including operations, features, circuitry, logic, means, or instructions, or any combination thereof for exposing at least some of an outer surface of the second dielectric material based at least in part on forming a second cavity of the plurality of second cavities.

Aspect 17: The method, apparatus, or non-transitory computer-readable medium of any of aspects 11 through 16, further including operations, features, circuitry, logic, means, or instructions, or any combination thereof for forming a plurality of first conductive paths at a first side of a pier of the plurality of piers and a plurality of second conductive paths at a second side of the pier, the plurality of first conductive paths and the plurality of second conductive paths dividing the memory component of the pier into a plurality of first memory cells and a plurality of second memory cells.

Aspect 18: The method, apparatus, or non-transitory computer-readable medium of aspect 17, where each of the plurality of first memory cells and each of the plurality of second memory cells are configured to store two or more bits of data.

Aspect 19: The method, apparatus, or non-transitory computer-readable medium of any of aspects 11 through 18, where the memory component includes a second stack of layers, the second stack of layers including a first layer of an oxide material, a second layer of the nitride material, and a third layer of the oxide material.

It should be noted that the described methods include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method for manufacturing a memory system, comprising:
forming a plurality of first pillars that extend through a stack of layers, each pillar of the plurality of first pillars comprising a first dielectric material, a second dielectric material, and a nitride material;
forming a plurality of first cavities extending through the stack of layers, each cavity of the plurality of first cavities positioned between a respective pair of first pillars of the plurality of first pillars;
forming a plurality of piers in the plurality of first cavities by forming one or more dielectric materials and a first conductive material, each pier comprising a core comprising a third dielectric material, a first layer coupled with an outer surface of the core comprising the first conductive material, and a memory component coupled with an outer surface of the first layer and comprising at least a fourth dielectric material;
forming a plurality of second cavities by removing the first dielectric material and the nitride material from the plurality of first pillars; and
forming a plurality of second pillars in the plurality of second cavities by forming a metal material and a second conductive material, each pillar of the plurality of second pillars comprising a core comprising the metal material and a second layer coupled with an outer surface of the core and an outer surface of the first layer of a respective pier, the second layer comprising the second conductive material.

2. The method of claim 1, wherein the stack of layers comprise at least a layer of the nitride material and a layer of a fifth dielectric material.

3. The method of claim 2, further comprising:
forming the memory component by removing a portion of the layer of the nitride material through a first cavity of the plurality of first cavities.

4. The method of claim 2, further comprising:
forming a void in the stack of layers by removing the layer of the nitride material; and
forming a layer of the metal material in the stack of layers by forming the metal material in the void.

5. The method of claim 1, further comprising:
forming a plurality of third cavities through the stack of layers; and
forming a plurality of second piers in the plurality of third cavities by forming the nitride material and a fifth dielectric, wherein forming the plurality of first cavities comprises:
removing the nitride material and fifth dielectric material from the plurality of second piers.

6. The method of claim 5, wherein a diameter of a first cavity of the plurality of first cavities is larger than a diameter of a third cavity of the plurality of third cavities.

7. The method of claim 5, further comprising:
exposing at least some of an outer surface of the first dielectric material of a first pillar of the plurality of first pillars based at least in part on forming a first cavity of the plurality of first cavities.

8. The method of claim 1, further comprising:
forming a plurality of first conductive paths at a first side of a pier of the plurality of piers and a plurality of second conductive paths at a second side of the pier, the plurality of first conductive paths and the plurality of second conductive paths dividing the memory component of the pier into a plurality of first memory cells and a plurality of second memory cells.

9. The method of claim 8, wherein each of the plurality of first memory cells and each of the plurality of second memory cells are configured to store two or more bits of data.

10. The method of claim 1, wherein the memory component comprises a second stack of layers, the second stack of layers comprising a first layer of an oxide material, a second layer of the nitride material, and a third layer of the oxide material.

11. A method for manufacturing a memory system, comprising:
forming a first cavity extending through a stack of layers, the stack of layers comprising a layer of a first dielectric material and a layer of a nitride material;
forming a second dielectric material in the first cavity;
forming a plurality of second cavities in the second dielectric material;
forming a plurality of piers in the plurality of second cavities by forming one or more dielectric materials and a first conductive material, each pier comprising a core comprising a third dielectric material, a first layer coupled with an outer surface of the core comprising the first conductive material, and a memory component coupled with an outer surface of the first layer and comprising at least a fourth dielectric material;
forming a plurality of third cavities in the second dielectric material, wherein each pier of the plurality of piers is positioned between a respective pair of third cavities of the plurality of third cavities; and
forming a plurality of pillars in the plurality of third cavities by forming a metal material and a second conductive material, each pillar of the plurality of pillars comprising a core comprising the metal material and a second layer coupled with an outer surface of the core and an outer surface of the first layer of a respective pier, the second layer comprising the second conductive material.

12. The method of claim 11, further comprising:
forming the memory component by removing a portion of the layer of the nitride material through a second cavity of the plurality of second cavities.

13. The method of claim 11, further comprising:
forming a void in the stack of layers by removing the layer of the nitride material; and
forming a layer of the metal material in the stack of layers by forming the metal material in the void.

14. The method of claim 11, further comprising:
forming a plurality of fourth cavities through the stack of layers; and
forming a plurality of second piers in the plurality of fourth cavities by forming the nitride material and a third dielectric, wherein forming the plurality of second cavities comprises:
removing the nitride material and the third dielectric material from the plurality of second piers.

15. The method of claim 14, wherein a diameter of a second cavity of the plurality of second cavities is larger than a diameter of a fourth cavity of the plurality of fourth cavities.

16. The method of claim 14, further comprising:
exposing at least some of an outer surface of the second dielectric material based at least in part on forming a second cavity of the plurality of second cavities.

17. The method of claim 11, further comprising:
forming a plurality of first conductive paths at a first side of a pier of the plurality of piers and a plurality of second conductive paths at a second side of the pier, the plurality of first conductive paths and the plurality of second conductive paths dividing the memory component of the pier into a plurality of first memory cells and a plurality of second memory cells.

18. The method of claim 17, wherein each of the plurality of first memory cells and each of the plurality of second memory cells are configured to store two or more bits of data.

19. The method of claim 11, wherein the memory component comprises a second stack of layers, the second stack of layers comprising a first layer of an oxide material, a second layer of the nitride material, and a third layer of the oxide material.

20. An apparatus for manufacturing a memory system, comprising:
one or more controllers configured to cause the apparatus to:
form a plurality of first pillars that extend through a stack of layers, each pillar of the plurality of first pillars comprising a first dielectric material, a second dielectric material, and a nitride material;
form a plurality of first cavities extending through the stack of layers, each cavity of the plurality of first cavities positioned between a respective pair of first pillars of the plurality of first pillars;
form a plurality of piers in the plurality of first cavities by forming one or more dielectric materials and a first conductive material, each pier comprising a core comprising a third dielectric material, a first layer coupled with an outer surface of the core comprising the first conductive material, and a memory component coupled with an outer surface of the first layer and comprising at least a fourth dielectric material;
form a plurality of second cavities by removing the first dielectric material and the nitride material from the plurality of first pillars; and
form a plurality of second pillars in the plurality of second cavities by forming a metal material and a second conductive material, each pillar of the plurality of second pillars comprising a core comprising the metal material and a second layer coupled with an outer surface of the core and an outer surface of the first layer of a respective pier, the second layer comprising the second conductive material.
